(19) United States
(12) Patent Application Publication
(10) Pub. No.: US 2006/0046370 A1
(43) Pub. Date: Mar. 2, 2006

(54) Method of manufacturing a transistor with void-free gate electrode

(76) Inventors: Yong-chul Oh, Suwon-si (KR); Wook-je Kim, Seoul (KR); Dong-gun Park, Seongnam-si (KR); Woun-suck Yang, Suwon-si (KR)

Correspondence Address: HARNESS, DICKEY & PIERCE, P.L.C., P.O. BOX 8910, RESTON, VA, 20195, US

(21) Appl. No.: 11/210,820

(22) Filed: Aug. 25, 2005

(30) Foreign Application Priority Data
Aug. 27, 2004 (KR) 2004-68009

(51) Int. Cl. H01L 21/8238; H01L 21/425; H01L 21/3205; H01L 21/4763

(52) U.S. Cl. 438/199; 438/514; 438/585

(57) ABSTRACT

A method of manufacturing a MOS transistor with a void-free gate electrode is provided. A gate oxide film may be formed on a semiconductor, and a poly silicon film for a gate electrode may be deposited on the gate oxide film. P-type impurities may be implanted into the poly silicon film, and a thickness of the poly silicon film may be removed by chemical mechanical polishing.

### BACKGROUND OF THE INVENTION

This application claims the priority of Korean Patent Application No. 2004-68009, filed on Aug. 27, 2004, in the Korean Intellectual Property Office, the disclosure of which is incorporated herein in its entirety by reference.

1. Field of the Invention

Example embodiments of the present invention relate to a method of manufacturing a transistor.

2. Description of the Related Art

A PMOS transistor may be used alone or in combination with an N-channel metal oxide semiconductor (NMOS) transistor to form a CMOS transmission. A CMOS transistor may be constructed by an NMOS transistor and a PMOS transistor, which may be electrically connected with each other and be complementary. CMOS transistors may have an operation speed and/or a characteristic similar to that of a bipolar transistor. Therefore the transistors may be adopted in a higher speed and higher performance.

Gate electrodes of an NMOS transistor and a PMOS transistor, which may construct a conventional CMOS transistor may be formed by an n+ poly silicon layer. In order to improve an integration characteristic of a CMOS transistor, for example, a speed characteristic of a PMOS transistor, a technique in which a gate electrode of an NMOS transistor may be formed by an n+ poly silicon layer and a gate electrode of a PMOS transistor may be formed by a p+ poly silicon layer may be used. This technique is called a dual gate technique. The n+ poly silicon layer may contain phosphorus (P) ions, and the p+ poly silicon layer contains boron (B) ions.

Boron ion may have a better diffusion characteristic compared to other ions. A compound of boron and a florin (F) may be ion-implanted, which may decrease the likelihood of boron penetrating a layer into which an ion may be implanted.

As an integration density of a semiconductor device increases, a line width of a gate electrode may decrease. A resistance of the gate electrode increases, and an operation speed of the device may be decreased. Then a doping density of the gate electrode or ion implantation energy may need to be increased in order to decrease a resistance of the gate electrode.

If an amount of BF₂ ions is increased by E15 ions/cm² or more, which may increase a conductivity of a gate electrode of a PMOS transistor, a florin component of the BF₂ ions may also increase. This increased florin component may damage a lattice of a poly silicon layer. A damaged poly silicon lattice may grow into a void with a heat applied in a subsequent heating process.

FIG. 1 is a photograph illustrating upper surfaces of gate electrodes of a related art NMOS transistor and a related art PMOS transistor after a heating process, and FIG. 2 is a sectional view of a gate electrode of a related art PMOS transistor after a heating process.

As shown in FIGS. 1 and 2, there may be no change after a heating process in case of a gate electrode of an NMOS transistor, however, a plurality of voids may be generated around an upper surface of a gate electrode after a heating process in case of a gate electrode of a related art PMOS transistor. A semiconductor substrate 10, a gate electrode 20, and a void 30 are illustrated in FIG. 2.

The void 30 generated in a gate electrode may deteriorate an electrical characteristic and/or reliability of the gate electrode.

### SUMMARY OF THE INVENTION

Example embodiments of the present invention provide methods of manufacturing transistors.

In an example embodiment of the present invention, a film may be deposited on a semiconductor substrate. Impurities may be ion-implanted into the semiconductor substrate, and the film may be partially removed.

In another example embodiment of the present invention, an insulation film may be formed on a semiconductor substrate. A poly silicon film may be deposited on the insulation film and impurities may be ion-implanted into the poly silicon film. A portion of the poly silicon film may be removed by a chemical mechanical polishing (CMP).

In another example embodiment of the present invention, an insulation film may be formed on a semiconductor substrate, which may include an NMOS (N-channel MOS) transistor area and a PMOS (P-channel MOS) transistor area. A poly silicon film may be deposited on the insulation film by a thickness greater than or equal to a thickness of a gate electrode. Impurities may be selectively ion-implanted into the poly silicon film of the PMOS transistor area, and at least a portion of the poly silicon film may be chemical mechanical polished.

In another example embodiment of the present invention, a first film may be formed on a substrate, and may include at least a first transistor area. A second film may be deposited on the first film, impurities may be selectively ion-implanted into the second film of the first transistor area, and at least a portion of the second film may be removed.

In example embodiments of the present invention, the film may be a poly silicon film, which may be non-doped poly silicon, and the impurities may contain a florin component, may be n-type impurities, may be p-type impurities, and/or may be BFₓ ions.

In example embodiments of the present invention, the film may be partially removed via chemical mechanical polishing, and the portion, which may be removed, may be greater than or equal to a depth of a range of penetration of the impurities.

In example embodiments of the present invention, the poly silicon film may be deposited to have a thickness greater than or equal to a thickness of a gate electrode.

In example embodiments of the present invention, the poly silicon film may be deposited to have a thickness greater than or equal to the thickness of the gate electrode by a thickness of 300 Å to 600 Å, inclusive, and/or the poly silicon film may be formed to have a thickness of 800 Å to 1600 Å, inclusive.

In example embodiments of the present invention, the p-type impurities may be ion-implanted such that a depth of a range of penetration of the impurities may be 200 Å to 400 Å, inclusive, from an upper surface of the poly silicon film.

In example embodiments of the present invention, wherein the poly silicon film may be chemical mechanical polished by a thickness greater than or equal to a depth of a range of penetration of the impurities.

In example embodiments of the present invention, the poly silicon film may be chemical mechanical polished by a thickness of 300 Å to 600 Å, inclusive.

In example embodiments of the present invention, the insulation film may be a gate insulation film.

In example embodiments of the present invention, the poly silicon film may have a thickness of 800 Å to 1600 Å, inclusive.

In example embodiments of the present invention, the selectively ion-implanting the impurities may further include forming a photo resist pattern on the NMOS transistor area such that the PMOS transistor area may be exposed, implanting BF2 ions into a poly silicon film of the exposed PMOS transistor area, removing the photo resist pattern, and activating impurities doped in the poly silicon film.

In example embodiments of the present invention, the BF2 ions may be ion-implanted such that a depth of a range of penetration of the BF2 ions may be 200 Å to 400 Å, inclusive, from an upper surface of the poly silicon film.

In example embodiments of the present invention, the BF2 ions may be ion-implanted at an ion implantation energy of 10 KeV to 30 KeV, inclusive, and at a density of 1015 ions/cm² to 1016 ions/cm², inclusive.

In example embodiments of the present invention, the method for manufacturing may further include forming a transition metal silicide film on the poly silicon film. A hard mask film may be formed on the transition metal silicide film, a NMOS gate electrode unit and a PMOS gate electrode unit may be formed by partially etching the hard mask film, the transition metal silicide film and the poly silicon film, and spacers may be formed on both sides of the NMOS and PMOS gate electrode units. Source/drain areas may be formed at both sides of the NMOS and PMOS gate electrode units.

In example embodiments of the present invention, a third film may be formed on the second film and a fourth film may be formed on the third film. At least a first gate electrode unit may be formed by partially etching the second film, third film and the fourth film. Spacers may be formed on both sides of the first gate electrode unit, and source/drain areas may be formed at both sides of the first gate electrode unit.

In example embodiments of the present invention, the first film may be an insulation film, the second film may be a poly silicon film, the third film may be a transition metal silicide film, and the fourth film may be a hard mask film.

### BRIEF DESCRIPTION OF THE DRAWINGS

Example embodiments of the present invention will become more apparent by describing in detail example embodiments thereof with reference to the attached drawings in which:

FIG. 1 illustrates upper surfaces of gate electrodes of a related art NMOS transistor and a related art PMOS transistor after a heating process;

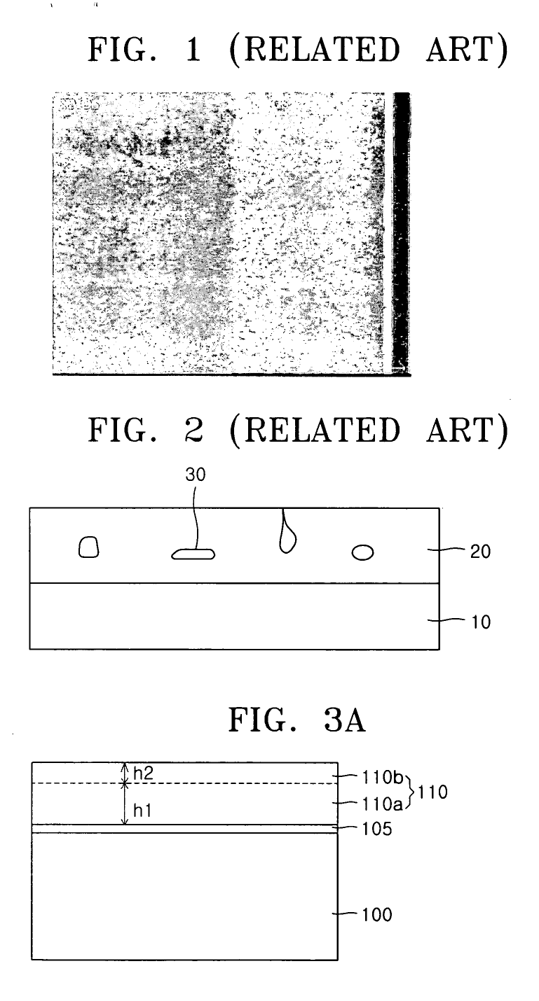

FIG. 2 is a sectional view of a gate electrode of a related art PMOS transistor after a heating process;

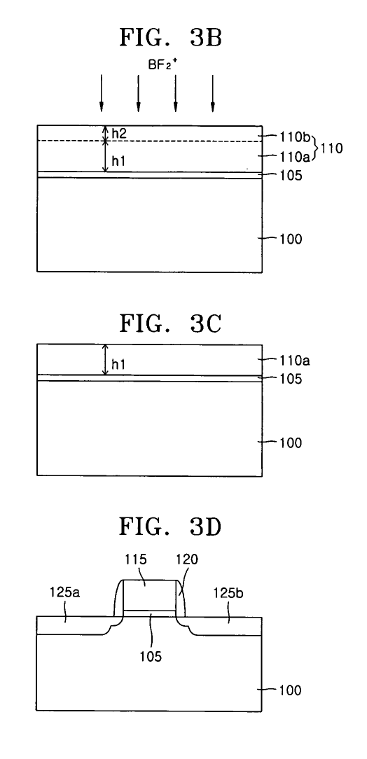

FIGS. 3A through 3D illustrate a method of manufacturing a PMOS transistor according to an example embodiment of the present invention; and

FIGS. 4A through 4D illustrate a method of manufacturing a CMOS transistor according to another example embodiment of the present invention.

### DETAILED DESCRIPTION OF THE EXAMPLE EMBODIMENTS OF THE INVENTION

Example embodiments of the present invention will be described more fully with reference to the accompanying drawings, in which example embodiments of the invention are shown. It should be understood, however, that example embodiments of the present invention described herein can be modified in form and detail without departing from the spirit and scope of the invention. Accordingly, the example embodiments described herein are provided by way of example and not of limitation, and the scope of the present invention is not restricted to the particular embodiments described herein.

In particular, the relative thicknesses and positioning of layers or regions may be reduced or exaggerated for clarity. Further, a layer is considered as being formed “on” another layer or a substrate when formed either directly on the referenced layer or the substrate or formed on other layers or patterns overlaying the referenced layer.

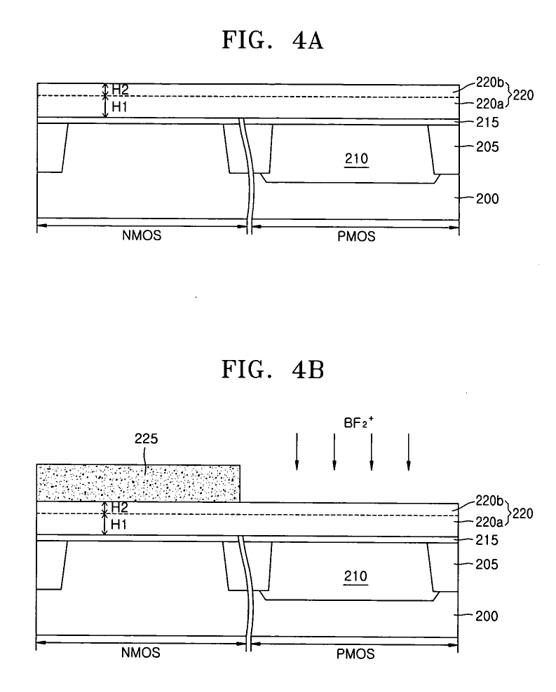

FIGS. 3A through 3D are step-by-step sectional views illustrating a method of manufacturing a transistor (e.g., a PMOS transistor) according to an example embodiment of the present invention. An example embodiment of the method of manufacturing a transistor will now be descried with reference to FIGS. 3A through 3D.

Referring to FIG. 3A, a gate oxide film 105 may be formed on a semiconductor substrate 100, for example, a silicon substrate doped with n-type impurities. A poly silicon film 110 may be deposited on the gate oxide film 105. The poly silicon film 110 may be deposited to have a thickness greater than or equal to a thickness (h1) of a gate electrode by another thickness (h2). That is, the thickness of poly silicon film 110 may be the sum of a thickness (h1) of a gate electrode and another thickness (h2). An area corresponding to “h1’ may be a first poly silicon film 10A, and an area corresponding to ‘h2’ may be a second poly silicon film 110B. For example, the first poly silicon film 110A, which may be used as a gate electrode, may have a thickness of approximately 500 Å to 1000 Å, inclusive, and the second poly silicon film 110B, which may be additionally deposited, may have a thickness of approximately 300 Å to 600 Å, inclusive. The poly silicon film 110 may have a thickness of approximately 800 Å to 1600 Å, inclusive. The poly silicon film 110 may not be doped with any impurities, or may be doped with n-type impurities.

Referring to FIG. 3B, in order to manufacture a gate electrode of the transistor, p-type impurities (Group III impurities), for example BF₂ ions may be implanted into the poly silicon film 110. A BF₂ ion may have improved diffusion efficiency. In order to reduce the likelihood of BF₂ ions from penetrating the gate oxide film 105, the range of penetration (RP) of the BF₂ ions may be adjusted to be located at an upper part of the poly silicon film 110. In example embodiments of the present invention, BF₂ ions may be ion-implanted at an ion implantation energy of approximately 10 KeV and 30 KeV and at a density of approximately 10¹⁵ ions/cm² and 10¹⁶ ions/cm² such that the RP of the BF₂ ions may have a depth of approximately 200 Å to 400 Å, inclusive, from an upper surface of the poly silicon film 110. The depth of the RP of the BF₂ ions may be controlled to be approximately 200 Å to 400 Å, inclusive, the RP of the BF₂ ions may be located within the second poly silicon film 110B, and silicon lattice defects and voids, may be generated within the second poly silicon film 110B.

Referring to FIG. 3C, the BF₂ ions implanted into the poly silicon film 110 may be activated, and a depth of the poly silicon film 110 may be removed (e.g., anisotropically removed). The poly silicon film 110 may be chemical mechanical polished, for example, by a depth of the RP, at which a density of the BF₂ ions may be improved (e.g., maximized), for example ‘h2’, whereby the first poly silicon film 110A may remain. Silicon lattice defects and/or voids, which may be caused by a florin component of the BF₂ ions, may exist within the second poly silicon film 110B, and removal of the second poly silicon film 110B may leave a void-free first poly silicon film 110A.

Referring to FIG. 3D, a given part of the poly silicon film 110A may be patterned, such that a gate electrode 115 may be formed. A spacer 120 may be formed on one or both sides of the gate electrode 115, for example, by any suitable method. P-type impurities may be implanted into portions of the semiconductor substrate 110, which may be located at one or both outsides of the gate electrode 115, at which source/drain areas 125A and 125B may be formed.

Example embodiments of the present invention, a poly silicon film for a gate electrode may be deposited to have a thickness that may be greater than or equal to a thickness of a gate electrode by another thickness, BF₂ ions may be implanted into the poly silicon film, and a part of the poly silicon film which may be damaged by the implantation of the BF₂ ions may be removed by, for example, a chemical mechanical polishing process. The remaining poly silicon film may be used as a gate electrode and may not include lattice defects and/or voids.

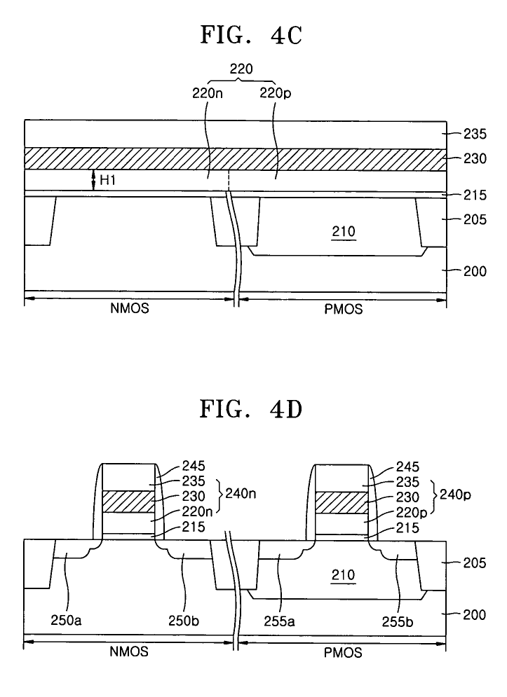

FIGS. 4A through 4D are step-by-step sectional views illustrating a method of manufacturing a transistor (e.g., a CMOS transistor) according to another example embodiment of the present invention. The example embodiments of the method of manufacturing a transistor will now be descried with reference to FIGS. 4A through 4D.

Referring to FIG. 4A, a dividing film 205 may be formed at portions of a semiconductor substrate 200, for example a silicon substrate doped with p-type impurities, by, for example, a well-known shallow trench isolation (STI) technique. The semiconductor substrate 200 may be divided into, for example, a NMOS transistor area and a PMOS transistor area by the dividing film 205. N-type impurities may be selectively implanted into the PMOS transistor area, which may form an n well 210.

The gate oxide film 215 may be deposited on the semiconductor substrate 200. A poly silicon film 220 for a gate electrode may be deposited on the gate oxide film 215. The poly silicon film 220 may be deposited and may have a thickness greater than or equal to a thickness (H1) of a gate electrode by a thickness (H2). An area corresponding to ‘H1’ may be a first poly silicon film 220A, and an area corresponding to ‘H2’ may be a second poly silicon film 220B. The first poly silicon film 220A may have the thickness H1, for example, a thickness of approximately 500 Å to 100 Å, inclusive, and the second poly silicon film 220B may have a thickness of approximately 300 Å to 600 Å, inclusive. The poly silicon film 220 may have a thickness of approximately 800 Å to 1600 Å, inclusive. The poly silicon film 220 may be doped with n-type impurities, for example, prior to being deposited.

Referring to FIG. 4B, a photo resist pattern 225 may be formed on the NMOS transistor area such that the poly silicon film 220 of the PMOS transistor area may be exposed. A dual gate electrode may be formed by implanting p-type impurities (Group III impurities), for example BF₂ ions into the poly silicon film 220 of the exposed PMOS transistor area. An ion implantation energy of the BF₂ ions may be adjusted according to a penetration characteristic of the BF₂ ions such that an RP of the BF₂ ions may be located at an upper part of the poly silicon film 220. In example embodiments of the present invention, the BF₂ ions may be ion-implanted at an ion implantation energy of approximately 10 KeV and 30 KeV and at a density of approximately 10¹⁵ ions/cm² and 10¹⁶ ions/cm² such that the RP of the BF₂ ions may have a depth of approximately 200 Å to 400 Å, inclusive, from an upper surface of the poly silicon film 220.

Referring to FIG. 4C, the photo resist pattern 225 may be removed and the poly silicon film 220 into which impurities may be ion-implanted, may be activated. An n-type poly silicon film 220n may be formed in the NMOS transistor area, and a p-type poly silicon film 220p may be formed in the PMOS transistor area. The poly silicon film 220 may be chemical mechanical polished by a thickness. The poly silicon film 220 may be chemical mechanical polished, for example, by a thickness greater than, or equal to, a depth of the RP, for example, ‘H2’. The RP of the BF₂ ions may be located at an upper part of the poly silicon film 220, and lattice defects and/or voids which may be caused by a florin component of the BF₂ ions, may be generated around the RP of the BF₂ ions. If the poly silicon film 220 is removed by a thickness greater than, or equal to, a depth of the RP of the BF₂ ions, all, or substantially all, of the lattice defects and/or voids may be removed. The remaining poly silicon film 220 may not have lattice defects and/or voids.

A transition metal silicide film 230 may be formed on the remaining poly silicon film 220. The transition metal silicide film 230 may be embodied, for example, by a film such as a tungsten silicide film, a titanium silicide film, a nickel silicide film, or any suitable film or combination thereof. A hard mask film 235 may be formed on the transition metal silicide film 230. The hard mask film 230 may be embodied by a silicon nitride film.

Referring to FIG. 4D, the hard mask film 235, the transition metal silicide film 230 and/or the poly silicon film 220 may be patterned, and gate electrode units 240n and 240p may be formed. Low-density and n-type impurities may be selectively implanted into portions of the semiconductor substrate 220, which may be located at one or both outsides of a NMOS gate electrode unit 240n, and low-density and p-type impurities may be selectively implanted into portions of the semiconductor substrate 220, which may be located at one or both outsides of a PMOS gate electrode unit 240p. The selective implantation process may be performed by, for example, a well-known photolithography process.

A spacer 245 may be formed on one or both sides of the gate electrode units 240n and 240p. High-density and n-type impurities may be selectively implanted into portions of the semiconductor substrate 220, which may be located at one or both outsides of the NMOS gate electrode unit 240n, and high-density and p-type impurities may be implanted into parts (i.e. the n well 210) of the semiconductor substrate 220, which may be located at one or both outsides of the PMOS gate electrode unit 240p, whereby lightly doped drain (LDD) type source/drain areas 250A, 250B, 255A and 255B.

In example embodiments of the method according to the present invention, a poly silicon film for a gate electrode may be deposited to have a thickness greater than, or equal to, a thickness of a gate electrode by another thickness, BF₂ ions may be implanted into the poly silicon film, and a portion of the poly silicon film may be damaged by the implantation of the BF₂ ions may be removed, for example, by a chemical mechanical polishing. The remaining poly silicon film used as a gate electrode may not have lattice defects and/or voids, which may be caused by the implantation of the BF₂ ions, which may improve electrical characteristics and/or reliability of the gate electrode.

Although example embodiments of the present invention have been described with respect to a poly silicon film, it will be understood that any suitable film may be used.

Although example embodiments of the present invention have been described with regard to BF₂ impurities, it will be understood that any suitable impurities may be utilized.

Although example embodiments of the present invention have been described with regard to a silicon substrate doped with n-type impurities, it will be understood that any suitable substrate may be utilized.

Although example embodiments of the present invention have been described with regard to anisotropic removal of a portion of the poly silicon film, it will be understood that portions of the poly silicon film may be removed using any suitable process.

Although example embodiments of the present invention have been described with regard to a shallow trench isolation technique, it will be understood that any suitable technique may be used to form a dividing film at portions of a substrate.

Although example embodiments of the present invention have been described with regard to a hard mask film of silicon nitride, it will be understood that the hard mask film may comprise any suitable material.

Although example embodiments of the present invention have been described with regard to n-type and/or p-type impurities, it will be understood that any suitable impurities may be utilized.

Although example embodiments of the present invention have been described with regard to LDD-type source/drain areas, it will be understood that any suitable source/drain areas may be utilized.

Although example embodiments of the present invention are discussed with respect to chemical mechanical polishing (CMP), it will be understood that any suitable polishing process may be used.

While example embodiments of the present invention have been particularly shown and described with reference to example embodiments thereof, it will be understood by those of ordinary skill in the art that various changes in form and details may be made therein without departing from the spirit and scope of the present invention as defined by the following claims.

What is claimed is:

1. A method of manufacturing a transistor, comprising:
depositing a film on a semiconductor substrate;
ion-implanting impurities into the semiconductor substrate; and
partially removing at least a portion of the film.

2. The method of claim 1, wherein the film is a poly silicon film.

3. The method of claim 1, wherein the impurities contains a florin component.

4. The method of claim 1, wherein the impurities are BFₓ ions.

5. The method of claim 1, wherein the film is partially removed via chemical mechanical polishing.

6. The method of claim 1, wherein the portion of the film removed is greater than or equal to a depth of a range of penetration of the impurities at which a density of the florin-containing impurities is maximized.

7. A method of manufacturing a transistor, comprising:
forming an insulation film on a semiconductor substrate;
depositing a poly silicon film on the insulation film;
ion-implanting impurities into the poly silicon film; and
removing at least a portion of the poly silicon film by chemical mechanical polishing (CMP).

8. The method of claim 7, wherein the impurities are p-type impurities.

9. The method of claim 7, wherein the poly silicon film is deposited to have a thickness greater than or equal to a thickness of a gate electrode.

10. The method of claim 7, wherein the poly silicon film is deposited to have a thickness greater than or equal to the thickness of a gate electrode by a thickness of 300 Å to 600 Å, inclusive.

11. The method of claim 7, wherein the poly silicon film is formed to have a thickness of 800 Å to 1600 Å, inclusive.

12. The method of claim 7, wherein the poly silicon film is non-doped poly silicon.

13. The method of claim 7, wherein the poly silicon film has n-type doped impurities.

14. The method of claim 7, wherein the p-type impurities are BFₓ ions.

15. The method of claim 7, wherein the p-type impurities are ion-implanted such that a depth of a range of penetration of the impurities, at which a density of the impurities is maximized, is 200 Å to 400 Å, inclusive, from an upper surface of the poly silicon film.

16. The method of claim 7, wherein the poly silicon film is chemical mechanical polished by a thickness greater than or equal to a depth of a range of penetration of the impurities, at which a density of the impurities is maximized.

17. The method of claim 7, wherein the poly silicon film is chemical mechanical polished by a thickness of 300 Å to 600 Å, inclusive.

18. A method of manufacturing a transistor, comprising:
forming an insulation film on a semiconductor substrate including an NMOS (N-channel MOS) transistor area and a PMOS (P-channel MOS) transistor area;
depositing a poly silicon film on the insulation film by a thickness greater than or equal to a thickness of a gate electrode;
selectively ion-implanting impurities into the poly silicon film of the PMOS transistor area; and
chemical mechanical polishing at least a portion of the poly silicon film.

19. The method of claim 18, wherein the insulation film is a gate insulation film.

20. The method of claim 18, wherein the impurities are p-type impurities.

21. The method of claim 18, wherein the poly silicon film is deposited to have a thickness greater than or equal to a thickness of the gate electrode by a thickness of 300 Å to 600 Å, inclusive.

22. The method of claim 18, wherein the poly silicon film is formed to have a thickness of 800 Å to 1600 Å, inclusive.

23. The method of claim 18, wherein the poly silicon film has n-type doped impurities.

24. The method of claim 18, wherein the selective ion-implanting further includes,
forming a photo resist pattern on the NMOS transistor area such that the PMOS transistor area is exposed,
implanting BF₂ ions into a poly silicon film of the exposed PMOS transistor area, removing the photo resist pattern, and
activating impurities doped in the poly silicon film.

25. The method of claim 24, wherein the BF₂ ions are ion-implanted so that a depth of a range of penetration of the BF₂ ions is 200 Å to 400 Å, inclusive, from an upper surface of the poly silicon film.

26. The method of claim 24, wherein the BF₂ ions are ion-implanted at an ion implantation energy of 10 KeV to 30 KeV, inclusive and at a density of 10¹⁵ ions/cm² to 10¹⁶ ions/cm², inclusive.

27. The method of claim 20, wherein the poly silicon film is chemical mechanical polished by a thickness greater than or equal to a depth of a range of penetration of the p-type impurities.

28. The method of claim 18, wherein the poly silicon film is chemical mechanical polished by a thickness of 300 Å to 600 Å, inclusive.

29. The method of claim 18, further including,
forming a transition metal silicide film on the poly silicon film,
forming a hard mask film on the transition metal silicide film,
forming a NMOS gate electrode unit and a PMOS gate electrode unit by partially etching the hard mask film, the transition metal silicide film and the poly silicon film,
forming spacers on both sides of the NMOS and PMOS gate electrode units, and
forming source/drain areas at both sides of the NMOS and PMOS gate electrode units.
